(19) United States
(12) Patent Application Publication
(10) Pub. No.: US 2025/0338958 A1
(43) Pub. Date: Nov. 6, 2025

(54) Systems and Methods for Efficient Cabinet Installation

(71) Applicant: Pronghorn Services, LLC, Prescott Valley, AZ (US)

(72) Inventor: Thomas Corkery, Prescott, AZ (US)

(21) Appl. No.: 19/197,908

(22) Filed: May 2, 2025

Related U.S. Application Data
(60) Provisional application No. 63/641,825, filed on May 2, 2024.

(51) Int. Cl. A47B 77/02; G06F 30/13

(52) U.S. Cl. CPC A47B 77/02; G06F 30/13

(57) ABSTRACT

Systems and methods for on-site installation of a cabinet unit are provided. The method includes providing, to a computer-implemented component selection module, floorplan data associated with a target space, wherein the floorplan data is associated with a complex target space. Using the component selection module, the system generates a component list including a list of components associated with the cabinet unit, wherein the component list includes no more than one side wall corresponding to each side of each cabinet module. The method further includes generating, with the component selection module, a packaging plan; packing the components into in accordance with a packaging plan; transporting the packed components to a site; and assembling the cabinet unit at the site.

### CROSS-REFERENCE TO RELATED APPLICATIONS

The present application claims priority to U.S. Provisional Patent App. No. 63/641,825, filed May 2, 2024 and entitled: SYSTEMS AND METHODS FOR EFFICIENT CABINET INSTALLATION, the entire contents of which are hereby incorporated by reference.

### TECHNICAL FIELD

The present invention relates, generally, to the field of novel housing construction methods and, more particularly, to the efficient installation of cabinet structures in the context of complex floorplans, such as kitchens, bathrooms, and the like.

### BACKGROUND

The installation of cabinet structures in residential and commercial settings traditionally involves assembling the cabinets in a dedicated factory, shipping the finished products to the building site, then installing the substantially finished structures in the appropriate space within the building or home. These pre-assembled cabinets (e.g., wall cabinets, base cabinets, pantry and oven cabinets, bathroom vanities, and other such structures) typically incorporate, when they leave the factory, any number of doors, shelves, face frames, and panels, as well as the hardware required for the cabinet unit.

Because pre-assembled cabinets are intended to be shipped in a number of modules that are later secured in place, the modules need to be structurally sound during transport. As a result, such cabinet modules are typically built to include, among other things, two or more vertical side panels attached to a base and backing structure. The opposing side panels of each module are then suitably fixed to each other side-by-side during installation at the site. This increases the number of panels as well as the overall weight of the modules that are shipped to the installation site.

There is therefore a long-felt need for cabinet installation methods that reduce cost and installation times while at the same time increasing overall build quality. Accordingly, systems and methods are therefore needed to overcome these and other limitations of the prior art.

### SUMMARY

The present subject matter generally relates to improved cabinet systems and methods of making and installing such cabinet systems that greatly reduce installation cost, material use, and complexity. In accordance with one embodiment, for example, a single vertical panel is used between adjacent spaces, rather than the two such panels as is typical of traditional pre-assembled units. The present invention is particularly focused on solving problems arising from the installation of cabinet units in “complex” target spaces, such as kitchens and bathrooms, where installation has to be performed in the presence of significant physical constraints present in the environment.

In accordance with one embodiment, a computer-implemented method of on-site installation of a cabinet unit includes: providing, to a computer-implemented component selection module, floorplan data associated with a target space, wherein the floorplan data is associated with a complex target space; generating, with the component selection module, a component list including a list of components associated with the cabinet unit, wherein the component list includes no more than one side wall corresponding to each side of each cabinet module; generating, with the component selection module, a packaging plan; packing the components into in accordance with a packaging plan; transporting the packed components to a site; and assembling the cabinet unit at the site. Assembly may be performed via human workers and/or robotic devices implementing advanced AI-based vision systems and the like. In accordance with one embodiment, a bracket is provided that is configured to be secured to a wall via a planar first portion, the bracket including a second planar portion configured at an angle of approximately 45 degrees relative to the planar first portion, and at least one panel that includes a cut-out configured to receive the bracket and allow the panel to remain in place during assembly. Other novel design features are also described herein.

### BRIEF DESCRIPTION OF THE DRAWING FIGURES

The present invention will hereinafter be described in conjunction with the appended drawing figures, wherein like numerals denote like elements.

FIG. 1 is a conceptual overview of cabinet installation method in accordance with one embodiment.

FIGS. 2-6 illustrate various views of a prototype cabinet structure in accordance with one embodiment.

FIGS. 7A-7C illustrate a method of assembling a cabinet structure in accordance with an example embodiment.

FIG. 8 illustrates an angled bracket in accordance with one embodiment.

FIG. 9 illustrates a cut-out in a panel configured to interface with the bracket of FIG. 8.

FIGS. 10 and 11 depict the use of a bracket of the type shown in FIGS. 8 and 9.

FIGS. 12A-12B depict a panel corner cut-out in accordance with one embodiment.

FIG. 13 depicts the use of a resilient insert within a slot in accordance with one embodiment.

FIGS. 14A-14B depict the use of dados to support a slide-in back in accordance with one embodiment.

### DETAILED DESCRIPTION

The present subject matter generally relates to improved cabinet systems and methods of making and installing those cabinet systems that greatly reduce installation cost, material use, and complexity. As a preliminary matter, it will be understood that the following detailed description is merely exemplary in nature and is not intended to limit the invention or the application and uses of the invention described herein. Furthermore, there is no intention to be bound by any theory presented in the preceding background or the following detailed description. In the interest of brevity, conventional and well-known techniques and components related to cabinet components, commercial and residential building construction, and architectural drawings need not be described herein.

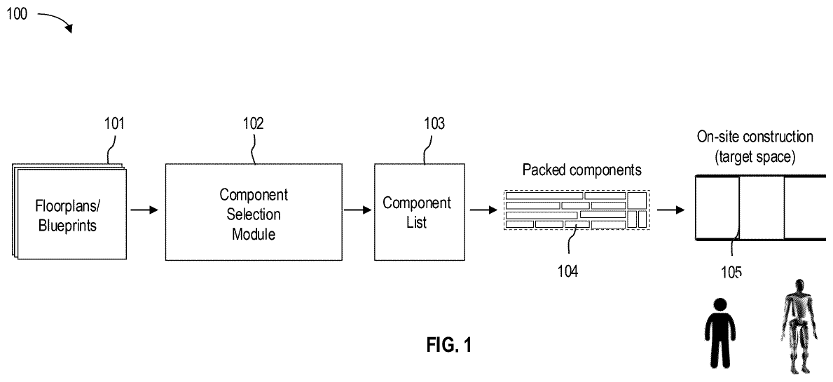

Referring now to the conceptual block diagram shown in FIG. 1, an example computer-implemented cabinet design system 100 will now be described. In general, component-selection module (or simply “module”) 102 is configured to receive a range of data 101 relating to the particular site and the types and sizes of cabinet units required at that site. Module 102 may receive floorplans and other blueprint data (in digital format or a physical format processed by a vision system) that specify the dimensions of the space in which the cabinet(s) are to be installed. This space may be referred to herein as the “target space,” and consists of a set of disjoint and/or contiguous three-dimensional regions in which the cabinets are to be installed. For example, in the context of floorplans 101 that include a kitchen, the target space may refer to a set consisting of an island region, a region adjacent to a stovetop/range, a region adjacent to a refrigerator unit, a region corresponding to a set of overhead cabinets, and the like. It will be appreciated that these examples, as with all examples in this document, are not intended to be limiting.

As described above, the present invention is focused on solving problems arising from the installation of cabinet units in “complex” target spaces, such as kitchens and bathrooms, where installation has to be performed in the presence of significant physical constraints present in the environment, such as the future location of kitchen appliances and the like. Thus, the present invention is not directed to the simple, rectangular target spaces addressed by closet installation.

Component-selection module 102 may include one or more databases for storing details relating to the range of panels, hardware, and other components available for a particular job, as well as information specifying the cabinets that are to be installed in the target space(s). Such details might include such factors as size, shape, weight, cost, availability, material, ornamental features, surface features, and any other attribute that might be relevant to cabinet design.

The databases may be implemented as a single database or multiple, distributed databases using a variety of database architectures and software known in the art. Stated another way, while various databases might be depicted as separate logical entities, they may in fact be implemented within the same physical database. Accordingly, the particular database contents and architectures depicted herein are not intended to be limiting. Similarly, the various documents and data illustrated in the figures may be stored in a variety of formats and data structures known in the art, such as unstructured text, structured text, associative arrays, spreadsheets, and any other data structure now known or later developed.

Component-selection module 102 may incorporate one or more AI or machine learning (ML) models that undergo supervised, unsupervised, semi-supervised, reinforcement, or assisted learning and perform classification (e.g., binary or multiclass classification), regression, clustering, dimensionality reduction, and/or such tasks in order to accomplish the cabinet-related tasks described herein. Such ML models might include, for example, convolutional neural networks (CNNs) or other vision systems (e.g., for interpreting the floorplans 101), decision tree models (such as classification and regression trees (CART)), ensemble learning models (such as boosting, bootstrapped aggregation, gradient boosting machines, and random forests), Bayesian network models (e.g., naive Bayes), principal component analysis (PCA), support vector machines (SVM), clustering models (such as K-nearest neighbor, K-means, expectation maximization, hierarchical clustering, etc.), and linear discriminant analysis models. In addition, data sets may be derived using natural language processing (NLP) or large language model (LLM) techniques, (e.g., for interpreting any information 101 provided to module 102).

As shown in FIG. 1, module 102 is configured to produce a component list 103 that lists all of the components, hardware, and other physical objects required for installation at the site. This component list 103 may be provided in any convenient digital format. In some embodiments, module 102 is also configured to produce a “packing plan” specifying the most efficient way that the selected components may be packed together for shipping to the site. This may be performed using a combination of the ML techniques described above, or may be specified using known heuristics relating to the packing of components for shipping.

Once the packed components 104 are received at the site (105), the desired cabinets are installed in accordance with the techniques described herein. Installation of the cabinets may be performed by human construction workers and/or one or more robots or robotic devices implementing AI-enhanced vision systems.

It will be understood that one of the ways that the present invention provides a significant advantage is that assembly and installation effectively occur at the same time. That is, there is no assembly prior to shipment of the components. The assembly occurs in situ at the same time that the components are installed in their final location. This is a significant advantage over the prior art, and greatly speeds up the assembly/installation process.

In accordance with one embodiment, the cabinets are installed in such a way that only one vertical panel is required between adjacent cabinet spaces, rather than the double-panel configuration required by pre-built designs. The present inventor has determined that this design feature results in a drastic reduction and material cost and installation time. Furthermore, each sidewall preferably has the same color and/or texture on all sides and edges, thereby simplifying construction and manufacture of each side panel.

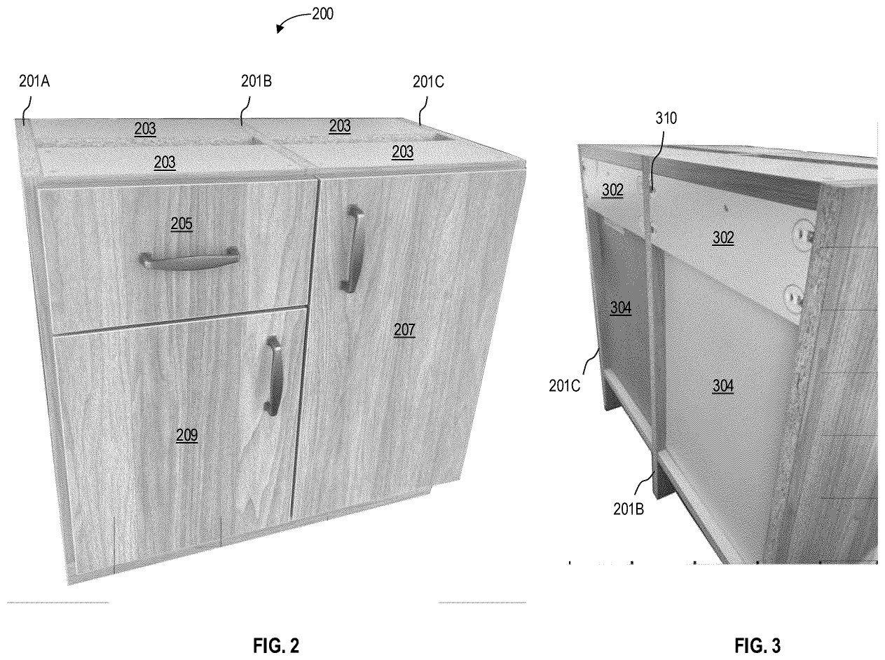

Referring now to FIGS. 2-6, a non-limiting example of a small cabinet design will now be described in order to illustrate various features. First, referring to the front view shown in FIG. 2, the cabinet unit 200 includes three substantially parallel side panels (201A, 201B, and 201C) which are suitably connected to upper rails 203, as shown. The cabinet unit 200 also includes a door panel 207 as well as drawer fronts 205 and 209 with related hardware. It will be understood that this configuration is often referred to as a “half-overlay reveal,” although other configurations are possible using the systems and methods of the present invention.

FIG. 3 illustrates the back side of the cabinet unit 200 shown in FIG. 2, and illustrates the attachment of nailers 302 to the side panels 201 using recessed connectors, such as “knock-down” (KD) connectors 310. FIG. 3 also illustrates back panels 304, which may slide into a bottom component via a tongue-and-groove joint, or may be affixed to one or more of the other components using any suitable method.

FIG. 4 is a view of the bottom 401 of the cabinet unit 200, including bottom panels 402 fixed to the side panels 201 via KD connectors 310, as well as a base comprising a toe kick 406, a toe-kick sub-front 408, and one or more vertical base components 404. FIG. 5 is a detail view 211 showing a side panel attached to shelf component via a KD connector, and FIG. 6 is a detail view 212 showing shelve components 601, 602 as installed within the unit.

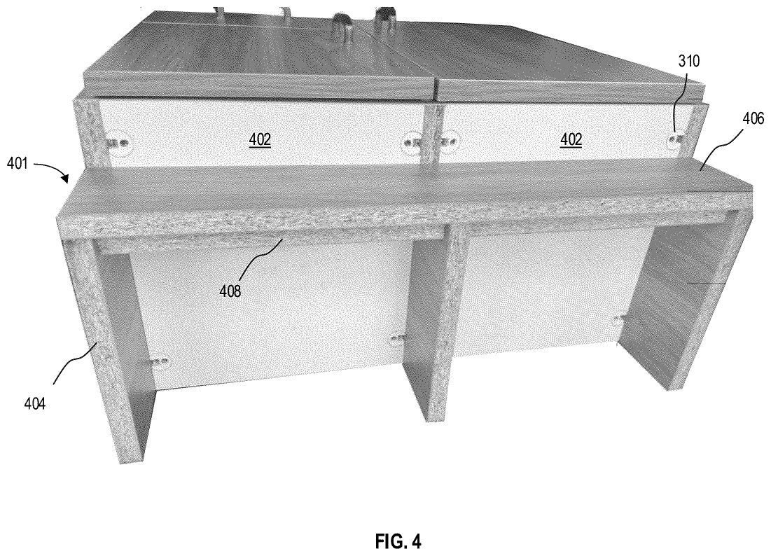

FIGS. 7A-7C depict installation of a cabinet unit at progressive steps (700) in the process. First, at FIG. 7A, a platform (or ladder toe-kick is installed), followed by attachment of the vertical panels to one or more horizontal components (FIG. 7(B)), and ultimately completion of the finished cabinet unit 703. This example is non-limiting; for example, the toe-kick components may be integrated into the individual sub-components (i.e., as shown in the foregoing figures), rather than being implemented as a single, ladder toe-kick as shown.

In general, in accordance with a preferred embodiment, assembly starts at a preexisting vertical surface (i.e., a wall defined within the floor plan) then working to the left or right, progressively adding cabinet units as necessary. In accordance with one embodiment, the process starts with providing one or more hanging tracks on the back wall, then begin adding the side panels. A nailer component may also be attached to the back wall. The bottom surface may then be put in place via KD connectors, as described above. The front and back top rails are then attached, followed by the bottom panel. Next, the back cleat is attached, and the backing component (e.g., quarter inch back) is slideably inserted through a groove in the base unit. Next, any adjustable shelfs are added, followed by the door panel(s), as appropriate. Installation continues by adding each side panel and building out the entire unit as desired.

FIGS. 7A-C show another example of a cabinet unit during assembly (701) and after assembly (703). It is apparent in FIG. 7B that a single vertical panel 702 is used between adjacent spaces, rather than the double-panel design that is typical of pre-assembled units.

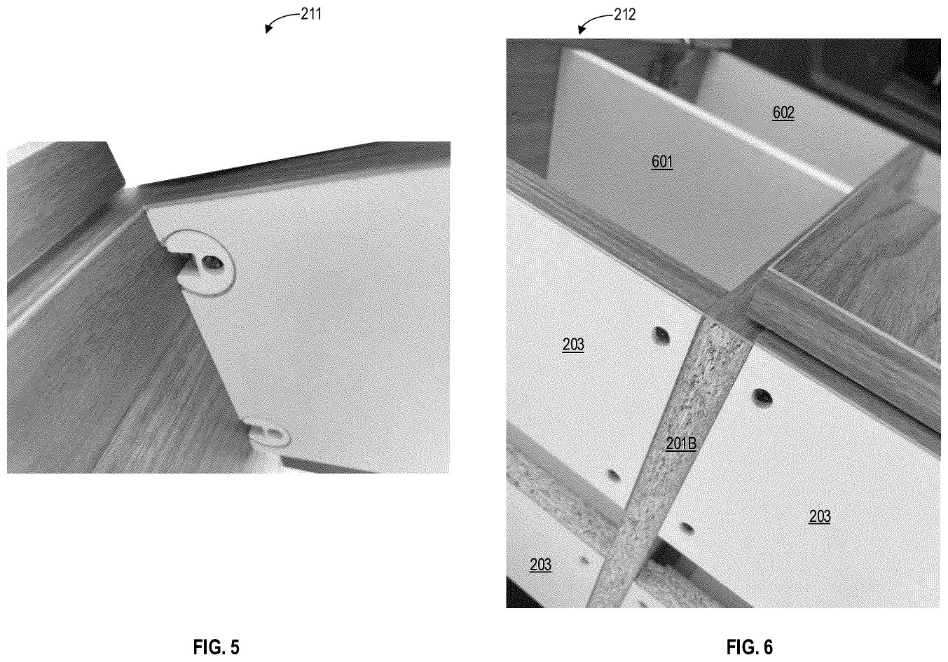

The present invention includes a number of other novel features, which together result in a significant reduction of installation labor while maintaining a high level of quality. For example, referring to FIG. 8, an angled bracket (or simply “bracket”) 800 may be provided to facilitate the installation of components against a wall or other vertical service in context in which it has traditionally been difficult to do so. More particularly, bracket 800 includes a first planar portion 803 including a plurality of mounting holes 804 that allow bracket 800 to be fixed to a back wall, as shown. Bracket 800 also includes a second planar portion 802 configured at a predetermined angle relative to first planar portion 803. This angle may range, for example, from 40-60 degrees, but in a preferred embodiment is approximately 45 degrees.

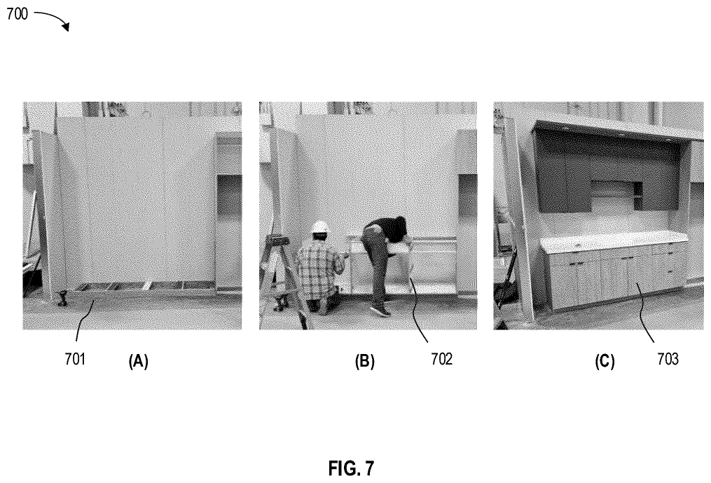

Bracket 800 is configured to interlock with a cut-out in a side panel, as shown in FIG. 9. That is, cut-out 900 in panel 901 includes a first portion 902 (having any desirable width) configured at the same angle depicted in FIG. 8 (i.e., from 40-60 degrees, preferably 45 degrees). Cut-out 900 also includes a second portion 903 configured to allow flush mounting of panel 901 (i.e., such that the edge of panel 901 does not contact portion 803 of bracket 800).

The present inventor has found that the use of bracket 800 in conjunction with cut-out 900 significantly reduces the time necessary to mount large, heavy panels to a back wall. That is, a worker need only lift the panel into place such that cut-out 900 engages bracket 800, and the panel or panels will be held in place for further mounting operations. Traditionally, such assembly would require two or more workers to align, hold, and secure large side panels in place.

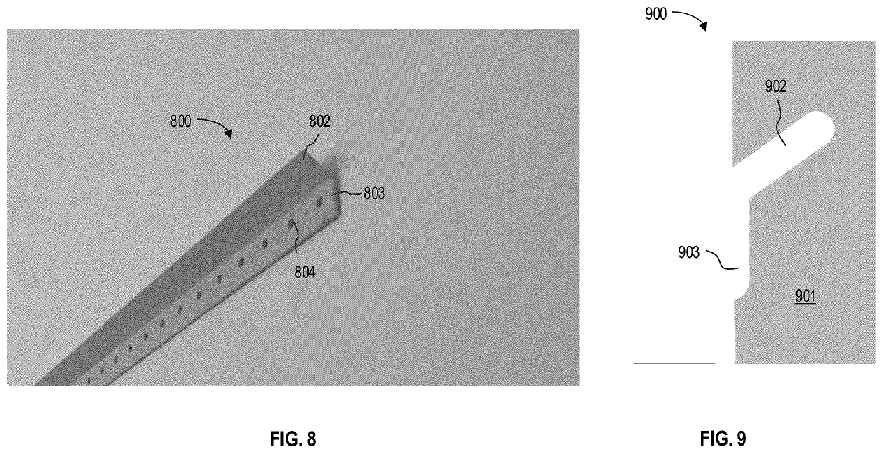

FIG. 10 shows an isometric overview of an example panel interfacing with a bracket such as that shown in FIG. 8 (detail 1000). Similarly, FIG. 11 is a cut-away view showing this interface (detail 1100).

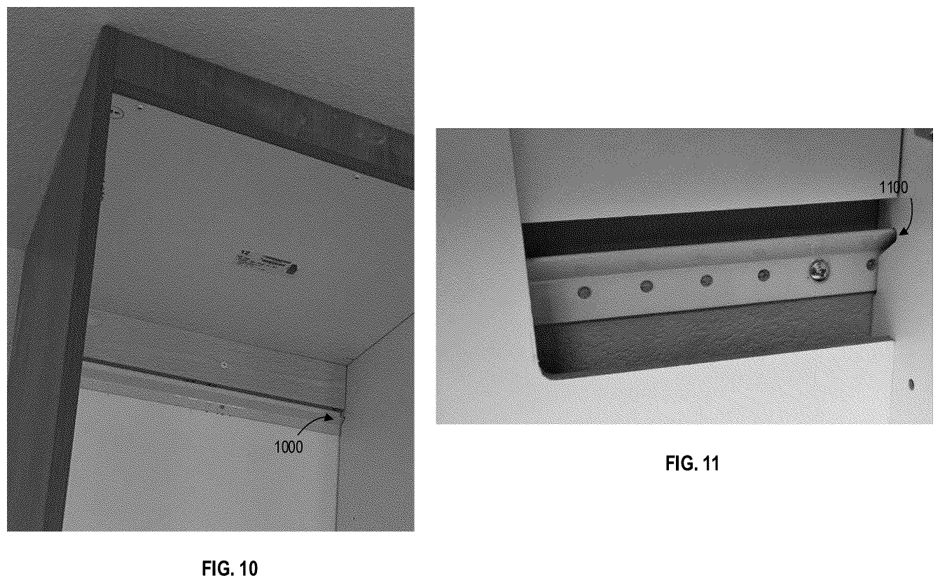

FIGS. 12A and 12B illustrate another panel feature that is advantageous in a cabinetry installation context. That is, a partial circular cut-out 1200 is provided at the corner of selected panels. This design feature, (formed using a router bit) allows a horizontal or vertical panel (i.e., a toe-kick, indicated with dotted lines) to lie flush with the edge of the panel that includes cut-out 1200. That is allows the square cut of toe kick (panel) to fit into a cut of a radius router bit, as shown in FIG. 12B.

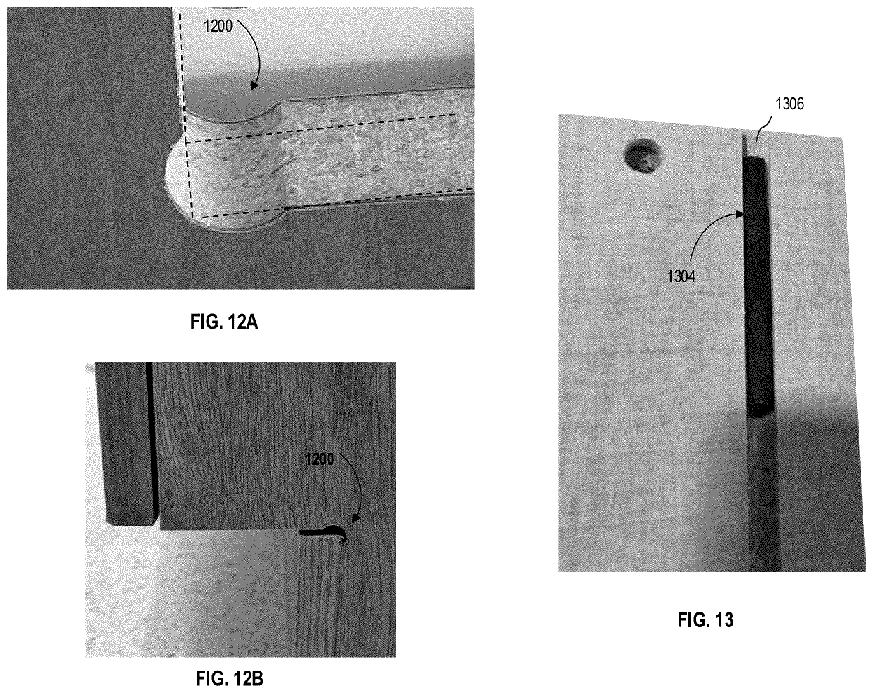

FIG. 13 illustrates yet another feature that improves the ultimate finish and assembly of the cabinet. That is, some panels may include a slot or groove 1306 configured to interface with the edge of another panel (e.g., a dado joint), wherein a resilient elongated component 1304 is inserted and is configured to provide compression to the side or end of a panel edge when inserted. This significantly increases both the functional and aesthetic features of the finished cabinet components, as it tends to reduce gaps between adjacent mating surfaces. The resilient component 1304 may be employed in a variety of ways.

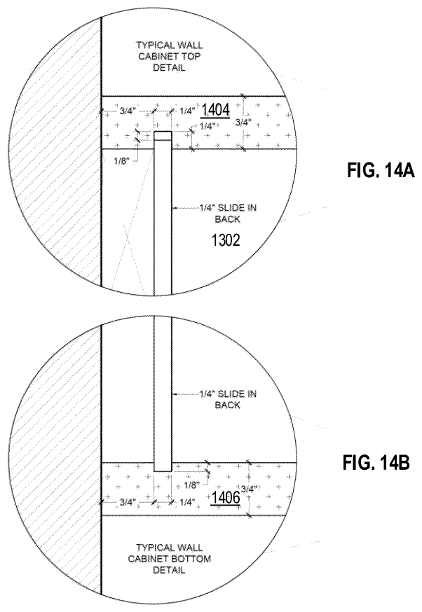

FIGS. 14A and 14B depict another advantageous feature in which the slide-in back (e.g., a ¼″ components) is inserted within a cabinet top (1404) and cabinet bottom (1406). In the illustrated embodiment, a ⅛″ dado is cut in cabinet bottom 1406, and a ¼″ dado is cut into cabinet top 1404. The total height of component 1302 is ¼″ less than the total distance between the two dado surface, as shown. This allows the component (slide-in back) to be inserted first in the upper dado (cut in 1404), and then lowered into the bottom dado (cut in 1406). This eases assembly while providing a flush appearance.

In summary, what has been described are improved cabinet systems and associated methods for complex installation jobs, wherein the cabinet units are built on-site using significantly less materials, and in substantially less time, than traditional pre-assembled cabinets.

What has also been described is a computer-implemented component-selection module that takes as its input floorplans, blueprints, and other information necessary to characterize the space in which the cabinet units are to be installed, and provides an optimized component list packing instructions for the components being shipped. Both of these aspects are particularly useful in housing construction, including, for example, affordable housing.

As used herein, the terms “module” or “controller” refer to any hardware, software, firmware, electronic control component, processing logic, and/or processor device, individually or in any combination, including without limitation: application specific integrated circuits (ASICs), field-programmable gate-arrays (FPGAs), dedicated neural network devices (e.g., Google Tensor Processing Units), graphics processing units (GPUs), virtual machines, electronic circuits, processors (shared, dedicated, or group) configured to execute one or more software or firmware programs, a combinational logic circuit, and/or other suitable components that provide the described functionality.

As used herein, the word “exemplary” means “serving as an example, instance, or illustration.” Any implementation described herein as “exemplary” is not necessarily to be construed as preferred or advantageous over other implementations, nor is it intended to be construed as a model that must be literally duplicated.

While the foregoing detailed description will provide those skilled in the art with a convenient road map for implementing various embodiments of the invention, it should be appreciated that the particular embodiments described above are only examples, and are not intended to limit the scope, applicability, or configuration of the invention in any way. To the contrary, various changes may be made in the function and arrangement of elements described without departing from the scope of the invention.

1. A method of on-site installation of a cabinet unit, the method comprising:
providing, to a computer-implemented component selection module, floorplan data associated with a target space, wherein the floorplan data is associated with a complex target space;
generating, with the component selection module, a component list including a list of components associated with the cabinet unit, wherein the component list includes no more than one side wall corresponding to each side of each cabinet module;
generating, with the component selection module, a packaging plan;
packing the components into in accordance with a packaging plan;
transporting the packed components to a site; and
assembling the cabinet unit at the site.

2. The method of claim 1, wherein the target space has a complexity that is greater than that of a closet space.

3. The method of claim 2, wherein the target space is selected from the group consisting of a kitchen space and a bathroom space.

4. The method of claim 2, wherein the assembling step is performed by a robotic device incorporating an AI-enhanced vision system.

5. The method of claim 1, wherein the component list includes a bracket configured to be secured to a wall via a planar first portion, the bracket including a second planar portion configured at an angle of approximately 45 degrees relative to the planar first portion, further wherein at least one panel provided within the component list includes a cut-out configured to receive the bracket and allow the panel to remain in place during assembly.

6. The method of claim 1, wherein the component list includes at least one panel having a slot formed therein and a resilient member configured to be seated within the slot to provide compression on a surface of a panel edge inserted within the slot.

7. The method of claim 1, wherein the component list includes two opposing panels, one including a first dado having a lower surface, the other including a second dado having an upper surface, wherein the second dado has a greater depth of the first dado, and the component list includes a component configured to interface with the first and second dados.

8. The method of claim 1, wherein the component list includes at least one panel having a circular cut-out provided at least one corner for accepting a horizontal toe-kick panel edge.

9. A method of on-site installation of a cabinet unit in a complex target space, the method comprising:
packing a plurality of cabinet components into in accordance with a packaging plan;
transporting the packed components to a site;
assembling the cabinet unit at the site, wherein the plurality of cabinet components are configured to allow the cabinet unit to be assembled with a single side panel between adjacent cabinet modules; and
the plurality of cabinet components includes a bracket configured to be secured to a wall via a planar first portion, the bracket including a second planar portion configured at an angle of approximately 45 degrees relative to the planar first portion, and at least one panel that includes a cut-out configured to receive the bracket and allow the panel to remain in place during assembly.

10. The method of claim 9, wherein the target space is selected from the group consisting of a kitchen space and a bathroom space.

11. The method of claim 9, wherein the assembling step is performed by a robotic device incorporating an AI-enhanced vision system.

12. The method of claim 9, wherein the plurality of cabinet components includes a bracket configured to be secured to a wall via a planar first portion, the bracket including a second planar portion configured at an angle of approximately 45 degrees relative to the planar first portion, further wherein at least one panel provided within the component list includes a cut-out configured to receive the bracket and allow the panel to remain in place during assembly.

13. The method of claim 8, wherein the plurality of cabinet components includes at least one panel having a slot formed therein and a resilient member configured to be seated within the slot to provide compression on a surface of a panel edge inserted within the slot.

14. The method of claim 9, wherein the plurality of cabinet components includes two opposing panels, one including a first dado having a lower surface, the other including a second dado having an upper surface, wherein the second dado has a greater depth of the first dado, and the component list includes a component configured to interface with the first and second dados.

15. A kit comprising a plurality of cabinet components for assembly at a remote site, the remote site including a complex target space, wherein the plurality of cabinet components include:
one or more cabinet components configured to allow the cabinet unit to be assembled with a single side panel between adjacent cabinet modules; and
a bracket configured to be secured to a wall via a planar first portion, the bracket including a second planar portion configured at an angle of approximately 45 degrees relative to the planar first portion, and at least one panel that includes a cut-out configured to receive the bracket and allow the panel to remain in place during assembly.
at least one panel having a slot formed therein and a resilient member configured to be seated within the slot to provide compression on a surface of a panel edge inserted within the slot; and
at least one panel having a circular cut-out provided at least one corner for accepting the edge of a horizontal panel.
